(19) United States
(12) Patent Application Publication
(10) Pub. No.: US 2024/0306385 A1
(43) Pub. Date: Sep. 12, 2024

(54) SEMICONDUCTOR DEVICE AND MANUFACTURING METHOD OF SEMICONDUCTOR DEVICE

(71) Applicant: SK hynix Inc., Icheon-si Gyeonggi-do (KR)

(72) Inventors: Won Geun CHOI, Icheon-si Gyeonggi-do (KR); Seok Min CHOI, Icheon-si Gyeonggi-do (KR); Rho Gyu KWAK, Icheon-si Gyeonggi-do (KR); Jung Shik JANG, Icheon-si Gyeonggi-do (KR); In Su PARK, Icheon-si Gyeonggi-do (KR)

(73) Assignee: SK hynix Inc., Icheon-si Gyeonggi-do (KR)

(21) Appl. No.: 18/346,663

(22) Filed: Jul. 3, 2023

(30) Foreign Application Priority Data
Mar. 10, 2023 (KR) 10-2023-0031550

(51) Int. Cl. H10B 43/27; H01L 23/528; H10B 41/10; H10B 41/27; H10B 43/10

(52) U.S. Cl. CPC H10B 43/27; H01L 23/5283; H10B 41/10; H10B 41/27; H10B 43/10

(57) ABSTRACT

A semiconductor device may include: a gate structure including conductive layers and insulating layers that are alternately stacked. Tapered supports formed in the gate structure layers have a first width at a first level of the layers and a second width smaller than the first width at a second level of the layers. A tapered contact structure is located between the tapered supports in the gate structure having a third width at the first level and a fourth width larger than the third width at the second level. The gate structure taper and the contact structure taper are “mirror images” of each other.

### CROSS-REFERENCE TO RELATED APPLICATION

This application claims priority under 35 U.S.C. § 119 (a) to Korean Patent Application No. 10-2023-0031550 filed on Mar. 10, 2023, in the Korean Intellectual Property Office, which is incorporated herein by reference in its entirety.

### BACKGROUND

### 1. Technical Field

Embodiments of the present disclosure relate to an electronic device, and more particularly, to a semiconductor device and a manufacturing method of the semiconductor device.

### 2. Related Art

The degree of integration of a semiconductor device is mainly determined by an area occupied by a unit memory cell. Recently, as the improvement in the degree of integration of a semiconductor device for forming memory cells in a single layer on a substrate reaches a limit, a three-dimensional semiconductor device for stacking memory cells on a substrate has been proposed. Furthermore, in order to improve the operational reliability of such a semiconductor device, various structures and manufacturing methods have been developed.

### SUMMARY

In an embodiment, a semiconductor device may include: a gate structure including conductive layers and insulating layers that are alternately stacked; tapered supports extending through the layers of the gate structure and each tapered support having a first width at a first level of the gate structure and a second width at a second level of the gate structure, the second width being smaller than the first width; and a tapered contact structure located within the gate structure, between the tapered supports, tapered contact structure having a third width at the first level of the gate structure and a fourth width at the second level of the gate structure, which is larger than the third width. In an embodiment, the taper of the supports and the taper of the contact structure are “mirror images” of each other, which is to say, the tapers have similar shapes and sizes but their orientations are reversed with reference to an intervening axis or plane between them.

In an embodiment, a semiconductor device may include: a gate structure including conductive layers and first insulating layers that are alternately stacked; supports extending through the layers of the gate structure; and a contact structure located between the supports in the gate structure, and electrically connected to at least one of the conductive layers, wherein the contact structure may include a first portion spaced apart from the supports and a second portion contacting the supports, and the gate structure may comprise the first insulating layers and second insulating layers that are alternately stacked between the supports and the first portion.

In an embodiment, a manufacturing method of a semiconductor device may include: forming a stack including first material layers and second material layers that are alternatively stacked; forming first openings in the stack; forming etch stop layers in the first openings; forming, in the stack, second openings located between the first openings; forming a third opening exposing the etch stop layer by etching the first material layers and the second material layers through the second openings; and removing first material layers remaining between the third opening and the etch stop layers.

In an embodiment, a manufacturing method of a semiconductor device may include: forming a stack including first material layers and second material layers that are alternatively stacked; forming sacrificial supports in the stack; forming, in the stack, a sacrificial contact structure located between the sacrificial supports; forming first openings in the stack by removing the sacrificial supports; replacing the first material layers around the sacrificial contact structure with insulating layers through the first openings; and forming supports in the first openings.

### BRIEF DESCRIPTION OF THE DRAWINGS

FIG. 1 is a diagram illustrating the horizontal cross-sectional structure of a semiconductor device in accordance with an embodiment.

FIGS. 2A and 2B are diagrams illustrating the structure of a semiconductor device in accordance with an embodiment.

FIG. 3 is a diagram illustrating the structure of a semiconductor device in accordance with an embodiment.

FIGS. 4A to 4E are diagrams illustrating the structure of a semiconductor device in accordance with an embodiment.

FIGS. 5A, 5B, 6A, 6B, 7A, 7B, 8A, 8B, and FIGS. 9 to 13 are diagrams for describing a manufacturing method of a semiconductor device in accordance with an embodiment.

FIG. 14A to 14G are diagrams for describing a method of manufacturing a semiconductor device in accordance with an embodiment.

### DETAILED DESCRIPTION

Various embodiments are directed to a semiconductor device having a stable structure and improved characteristics and a manufacturing method of the semiconductor device.

By stacking memory cells in three dimensions, it is possible to improve the degree of integration of a semiconductor device. Furthermore, it is possible to provide a semiconductor device having a stable structure and improved reliability.

Hereafter, embodiments in accordance with the technical spirit of the present disclosure will be described with reference to the accompanying drawings. Among other things, the drawings show cross sections of various structures, such as alternating layers of different materials and other features. Cross sections can be either horizontal or vertical. As horizontal cross section cuts through an object in a horizontal direction, i.e., in a direction parallel to the object's base. A vertical cross section cuts through an object the vertical direction. i.e., in a direction perpendicular to the object's base.

Interleaved layers are considered herein as layers of different materials that are arranged in alternating layers. By way of example, two layers of a first type of material that are separated from each other by a second and different type of material are layers that are interleaved.

As used herein and for claim construction purposes, the word “line” refers to any electrically conductive path formed in the semiconductor device and which is electrically connected to semiconductor devices or components thereof, which are formed in the device. A line can thus electrically connect transistors to each other. A line can also connect transistors to externally-accessible contact surfaces through which signals can be provided into and received from the memory device. While the word “line” may imply straight or substantially straight shape requirement, the lines referred to herein, may have shapes that are not straight and which may be, and usually are, quite circuitous.

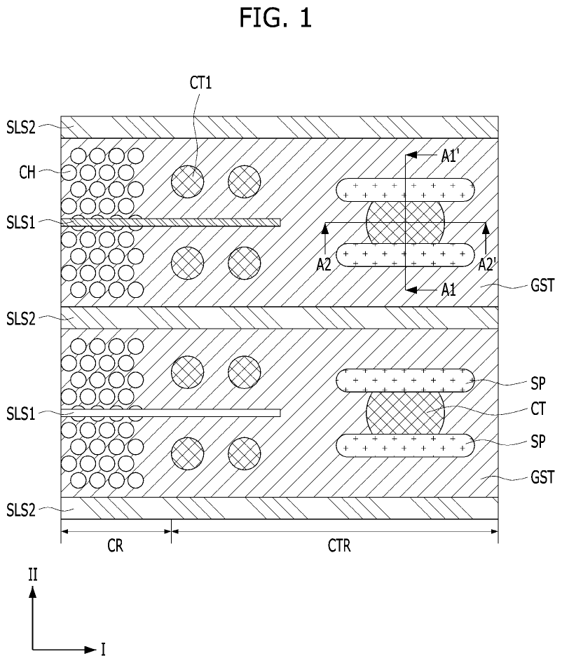

FIG. 1 is a diagram illustrating the structure of a semiconductor device in accordance with an embodiment.

Referring to FIG. 1, the semiconductor device may include a gate structure GST, supports SP, and a contact structure CT, or a combination thereof. The semiconductor device may further include channel structures CH, a first slit structure SLS1, a second slit structure SLS2, a first contact structure CT1, or a combination thereof.

The gate structure GST may include a cell region CR and a contact region CTR. The cell region CR may be a region where memory cells are stacked. The contact region CTR may be a region where an interconnection structure for driving each memory cell of the stacked memory cells is located. The gate structure GST may extend in a first direction I. As shown in FIG. 1, the cell region CR and the contact region CTR may be contiguous, i.e., in actual contact and thus adjacent to each other in the first direction I.

Channel structures CH may be located in the gate structure GST. The channel structures CH may be located in the cell region CR. The memory cells may be stacked along the channel structure CH. The semiconductor device may include vertical electrode structures instead of the channel structures CH. In such a case, the memory cells may be stacked along the vertical electrode structure.

As shown in FIG. 1, a first slit structure SLS1 may be located in the gate structure GST, within the cell region CR. The first slit structure SLS 1 may extend through the cell region CR in the first direction I into the contact region CTR. As an example, the first slit structure SLS1 may be used to pattern source select lines or drain select lines, and may have a depth that extends into the plane of FIG. 1, i.e., in a third direction mutually orthogonal to the first direction I and second direction II, by which the first slit structure SLS1 partially passes through the gate structure GST. The first slit structure SLS1 may include an insulating material such as oxide, nitride, or an air gap. The first slit structure SLS1 may overlap the channel structures CH or may be located between the channel structures CH. The channel structures CH overlapping the first slit structure SLS1 may be a real channel structure or a dummy channel structure.

A second slit structure SLS2 may be located between and separating gate structures GST that are not contiguous but nevertheless considered to be “adjacent” each other in the second direction II, which is orthogonal to and intersecting the first direction I. The second slit structure SLS2 may extend in the first direction I and may separate the gate structures GST from each other. As an example, the second slit structure SLS2 may have a greater depth in the third direction than the depth of the first slit structure SLS1. The second slit structure SLS2 may also have a depth by which the second slit structure SLS2 extends completely through the gate structure GST, which cannot be shown in FIG. 1 because FIG. 1 is a horizontal cross section. The second slit structure SLS2 may include an insulating material such as oxide, nitride, or an air gap on its exterior surfaces, i.e., surfaces that “face” the gate structures, GST. Alternatively, the second slit structure SLS2 may include a source contact structure electrically connected to a source structure.

Supports, SP, may be located in the gate structure GST and may be located withing the contact region CTR. As an example, a pair of supports, SP, may be spaced apart from each other in the second direction II but nevertheless “facing” each other.

As shown in FIG. 1, a contact structure, CT, may be located in the gate structure GST, between the supports, SP. As an example, the contact structure CT may be electrically connected to a word line, a source select line, or a drain select line, not shown in FIG. 1.

A first contact structure CT1 may be located in the contact region CTR. The first contact structure CT1 may be located between the channel structures CH and the contact structures CT. The first contact structure CT1 may be located between the first slit structure SLS1 and the second slit structure SLS2. As an example, the first contact structure CT1 may be electrically connected to a drain select line or a source select line.

According to the structure described above, the contact structure CT may be located between the supports SP adjacent to each other in the second direction II. The contact structure CT may contact the supports SP, and the size of the contact structure CT may be determined by the supports SP.

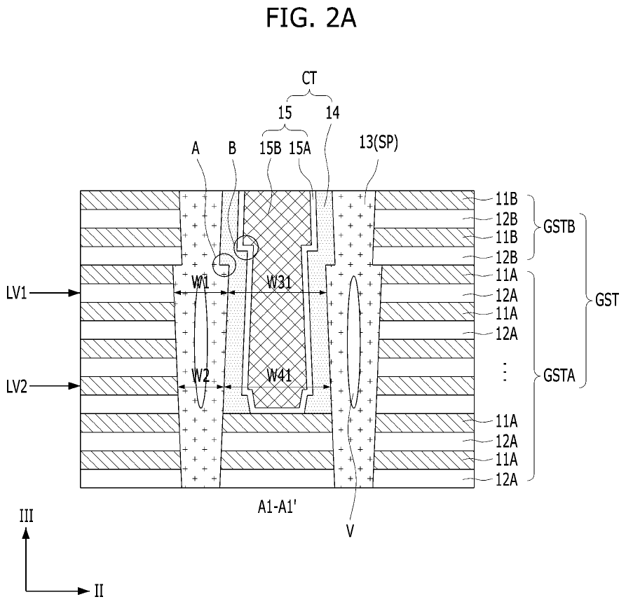

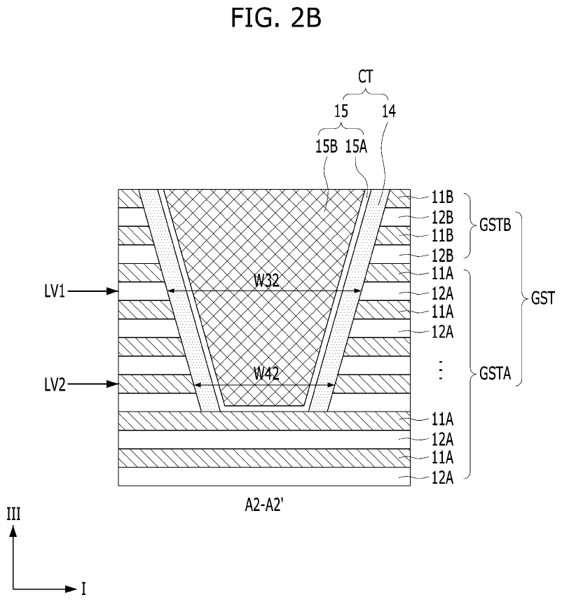

FIGS. 2A and 2B are vertical cross-sectional diagrams illustrating the structure of a semiconductor device in accordance with an embodiment. More particularly, FIG. 2A may be a vertical cross-sectional view taken along section line A1-A1′ in FIG. 1. FIG. 2B may be a cross-sectional view taken along section line A2-A2′ in FIG. 1. Descriptions of features that are-described above will hereafter be omitted in the interest of brevity and clarity.

Referring to FIGS. 2A and 2B, the gate structure GST may include a first substack GSTA and a second substack GSTB. The first substack GSTA may include conductive layers 11A and insulating layers 12A that are interleaved with each other, i.e., alternately stacked. The second substack GSTB may include conductive layers 11B and insulating layers 12B that are also interleaved with each other, i.e., alternately stacked. The first substack GSTA may be a “lower” stack. i.e., lower with respect to the second substack GSTB. The second substack GSTB may be an “upper” stack relative to the lower substack GSTA. The first substack GSTA may alternatively be an upper stack and the second substack GSTB may alternatively be a lower stack.

The conductive layers 11A and 11B may be gate lines such as word lines, bit lines, and select lines. As an example, a lowermost conductive layer 11A may be a source select line, and an uppermost conductive layer 11B may be a drain select line. Other conductive layers 11A and 11B located between the lowermost and uppermost layers may be word lines. The conductive layers 11A and 11B may each include a conductive material such as polysilicon, tungsten, or molybdenum. The insulating layers 12A and 12B may be used to insulate the stacked conductive layers 11A and 11B from each other, and may include an insulating material such as oxide, nitride, or an air gap.

Supports 13 may be located in the gate structure GST and may extend in a third direction III, mutually orthogonal to the first direction I and the second direction II, as shown in FIGS. 2A and 2B. The third direction III may be the direction in which the conductive layers 11A and 11B are stacked. The supports 13, each of which may include an insulating material such as oxide or nitride, may be used to support insulating layers 12A and 12B when sacrificial layers are replaced with the conductive layers 11A and 11B in a manufacturing process.

As used herein, a taper is a gradual change in thickness, diameter, or width, of an elongated object. In some embodiments, the supports 13 may have a uniform width. In other embodiments, the supports may also have a taper, i.e., the supports are tapered and thus have different horizontal cross-sectional dimensions, e.g., different widths or diameters, at different locations (or levels) along the length of a support 13 in the third direction III. In FIG. 2A, the support 13 depicted on the left side of the contact structure CT is shown as having a first width W1 at a first level LV1, and a second width W2, smaller than the first width W1, at a second level LV2. The first level LV1 and the second level LV2 may be located in the same substacks STA and STB. As an example, in the first substack GSTA, a lower portion of the support 13 may have a smaller width than an upper portion thereof. The support 13 depicted on the right-hand side of the contract structure CT may have the widths W1 and W2 at levels LV1 and LV2 respectively. In an alternate embodiment, however, the left-side support 13 and the right-side support may be configured such they have different widths W1 and W2 at levels LV1 and LV2 or conversely, or the widths W1 and W2 may be located at different levels, i.e., not LV1 and LV2.

Regardless of whether the support 13 has a uniform width or is tapered, the support 13 may include a protuberance or step, A, formed in or on the sidewall of the support 13. The step, A, extends all the way around the support 13 and may be located at a location in the third direction III, which is at, or at least proximate to an interface between the first substack GSTA and the second substack GSTB. The step, A, may be formed by repeatedly etching an opening for the support 13. When a first opening in the first substack GSTA and a second opening in the second substack GSTA are formed through separate processes, the step, A, may be located where the first opening and the second opening are connected to each other, and may be an inflection point where at the sidewall's taper, i.e., the inclination angle of the sidewall of the support 13 is changed.

The support 13 may include at least one internal void, V. The void V may be an empty space caused by a deposition process used to form the support 13. The void, V, may be located in different portions of the support 13. As an example, the void V may be located in a region of the support 13 having a relatively wide width. As best seen in FIG. 1, the contact structure CT may be located between and abutting supports 13. As an example, the contact structure CT may be located between the supports 13, which are separated from each other in the second direction II by a distance substantially equal to a thickness of the contact structure CT. The contact structure CT, and the supports 13, may extend “downwardly” into the plane of FIG. 1, which is in the third direction III. As shown in FIGS. 2A and 2B, the contact structure CT may be mechanically connected to at least one of the conductive layers 11A and 11B. The contact structure CT may also be electrically coupled to at least one of the conductive layers 11A and 11B.

As best seen in FIG. 2A and 2B, the contact structure CT may include a contact plug 15 and an insulating spacer 14, which is in contact with and extends along a sidewall of the contact structure CT. The contact plug 15 may include a barrier layer 15A and a metal layer 15B in the barrier layer 15A. As an example, the barrier layer 15A formed on the outside surface of the contact plug 15 and extending all the way around that outside surface, may include metal nitride. A metal layer 15B, “within” or encircled by the barrier layer 15A, may include metals such as tungsten or molybdenum or equivalents thereof. An insulating spacer 14 may be formed, which surrounds the barrier layer 15A, the insulating spacer 14 and the metal layer 15B as described above and as shown in FIG. 2A. A lower surface of the contact plug 15 might not be surrounded by the insulating spacer 14 and may contact at least one of the conductive layers 11A and 11B.

The contact structure CT may be formed to have a width that is uniform or at least substantially uniform. The contact structure CT may also be formed with a taper and thus have a width that changes continuously between the top and bottom of the contact structure CT, the contact structure CT having different widths at different levels.

Referring to FIG. 2A, the contact structure CT may have a third width W31 at the first level LV1 and a fourth width W41 greater than the third width W31 at the second level LV2. The first level LV1 and the second level LV2 may be located in the same substacks STA and STB. As an example, in the first substack GSTA, a lower portion of the contact structure CT may have a smaller width than an upper portion thereof.

The contact structure CT may have different shapes, which of course have correspondingly-different cross-sectional shapes. Different cross-sectional shapes thus correspond to and identify different shapes. Differently-shaped contact structures CT may therefore have different horizontal cross-sectional shapes and different vertical cross-sectional shapes. In that regard, FIG. 1 depicts the horizontal cross section of contact structure CT. FIGS. 2A and 2B depict vertical cross sections of the contact structure CT. Different shapes that the contact structure CT may have are rectilinear, which are three-dimensional shapes comprised of straight or substantially straight lines. In one such alternate embodiment, the shape of the contact structure CT is substantially the same as a parallelepiped, which is a 6-faced polyhedron all of whose faces are parallelograms lying in pairs of parallel planes. In another embodiment, the shape of the contact structure CT is substantially the same as a pyramid, which is a polyhedron having for its base a polygon and for faces, triangles with a common vertex. In yet another embodiment, the shape of the contact structure CT is substantially the same as a truncated pyramid.

Referring to FIG. 2B, the contact structure CT, which is tapered. may have a third width W32 at the first level LV1 and a fourth width W42 smaller than the third width W32 at the second level LV2. As an example, the tapered contact structure CT may have a relatively narrow bottom width in the vertical cross section defined by the second direction II and the third direction III, and have a wide top width in the cross section defined by the first direction I and the third direction III.

As shown in FIG. 2A, the contact plug 15 may include a step B on the sidewall thereof. The step B may be formed by transferring step A of the supports 13 in the manufacturing process. The step B may be located at an interface between the first substack GSTA and the second substack GSTB or located in the second substack GSTB.

The semiconductor device may include a plurality of contact structures CT. As an example, the contact structures CT may be located in the gate structure GST at different depths, and may be connected to the conductive layers 11A and 11B, respectively.

According to the structure described above, the contact structure CT may be located between the supports 13 and may contact the supports 13. Accordingly, when the supports 13 each have a tapered cross section, the contact structure CT may have a reversed tapered cross section. Because the sidewalls of the supports 13 contact the sidewalls of the contact structure CT, damage to peripheral layers due to material layers remaining between the contact structure CT and the supports 13 can be prevented or reduced. As an example, sacrificial layers between the contact structure CT and the supports 13 that might occur during a manufacturing process can be prevented or reduced, or remaining of a source gas in the process of replacing the sacrificial layers with the conductive layers 11A and 11B can be prevented or reduced.

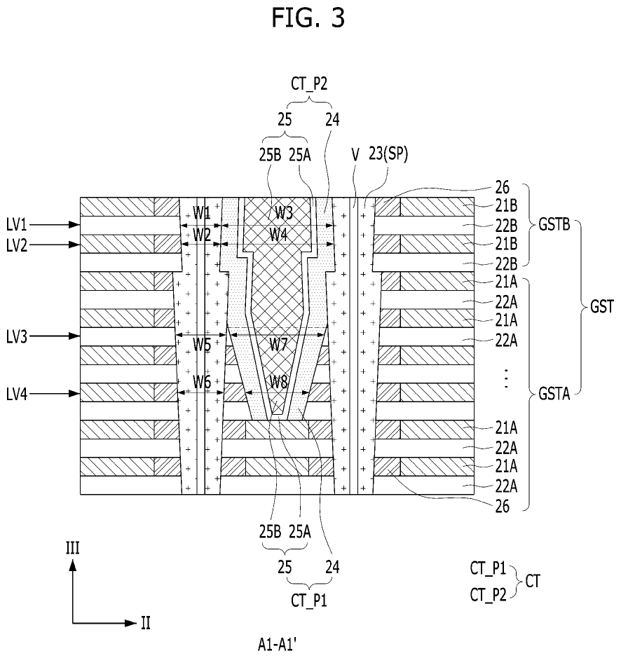

FIG. 3 is a vertical cross section diagram illustrating the structure of a semiconductor device in accordance with an embodiment. FIG. 3 may be a vertical cross-sectional view taken along line A1-A1′ of FIG. 1. Hereinafter, descriptions of previously described content is omitted in the interest of brevity.

Referring to FIG. 3, the gate structure GST may include conductive layers 21A and 21B, which are interleaved with first insulating layers 22A and 22B. Interleaved layers means that pairs of conductive layers 21A or 21B are separated from each other by an insulating layer 22A or 22B. Stated another way, pairs of insulating layers are separated from each other by a conductive layer. The conductive layers 21A and 21B may be gate lines such as word lines, bit lines, and select lines. Supports 23 may be located in the gate structure GST and may extend in the third direction III.

The supports 23 may have a uniform width or may be tapered and thus have different widths along the depth, or penetration, of a support 13 in the third direction. In a second substack GSTB, the support 23 may have a first width W1 at a first level LV1 and a second width W2 smaller than the first width W1 at a second level LV2. As an example, in the second substack GSTB, a lower portion of the support 23 may have a smaller width than an upper portion thereof.

In a first substack GSTA, the support 23 may have a fifth width W5 at a third level LV3 and a sixth width W6 smaller than the fifth width W5 at a fourth level LV4. As an example, in the first substack GSTA, the lower portion of the support 23 may have a smaller width than the upper portion thereof.

Each of the supports 23 may include a step A on the sidewall thereof. The support 23 may include at least one void V located therein. The support 23 may include the void V only in a partial region or may include the void V as a whole.

A contact structure CT may be located between the supports 23 in the gate structure GST. As an example, the contact structure CT may be located between the supports 23 adjacent to each other in the second direction II. The contact structure CT may extend along the third direction III, and may be electrically connected to at least one of the conductive layers 21A and 21B.

The contact structure CT may include a contact plug 25 and an insulating spacer 24. The contact plug 25 may be electrically connected to at least one of the conductive layers 21A and 21B. The contact plug 25 may include a barrier layer 25A and a metal layer 25B in the barrier layer 25A. The insulating spacer 24 may surround sidewalls of the contact plug 25. A lower surface of the contact plug 25 might not be surrounded by the insulating spacer 24 and may contact the conductive layers 21A and 21B.

The contact structure CT may include a first portion CT_P1 at or near the “bottom” of the contact structure CT. The contact structure may also have a second portion CT_P2, which is “above” and physically connected to the first portion CT_P1. The first portion CT_P1 may be located in the first substack GSTA. The second portion CT_P2 may be located in the second substack GSTB, and may extend into the first substack GSTA.

The second portion CT_P2 may contact the supports 23. The second portion CT_P2 may have a uniform width or it may be tapered and may thus have different widths at different depths in the third direction III. Various depths are referred to herein as regions. In the second substack GSTB, the second portion CT_P2 may have a third width W3 at the first level LV1 and a fourth width W4 greater than the third width W3 at the second level LV2. As an example, in the second substack GSTB, a lower portion of the second portion CT_P2 may have a larger width than an upper portion thereof.

The first portion CT_P1 may be spaced apart from the supports 23. The first portion CT_P1 may have a uniform width or may have different widths according to regions. In the first substack GSTA, the first portion CT_P1 may have a seventh width W7 at the third level LV3 and an eighth width W8 smaller than the seventh width W7 at the fourth level LV4. As an example, in the first substack GSTA, a lower portion of the first portion CT_P1 may have a smaller width than an upper portion thereof.

The first insulating layers 22A and 22B and second insulating layers 26 may be alternately stacked between the first portion CT_P1 and the supports 23. The gate structure GST may be located between the first portion CT_P1 and the supports 23, and may include the first insulating layers 22A and 22B and the second insulating layers 26 that are alternately stacked. The second insulating layers 26 may be located at levels corresponding to the conductive layers 21A and 21B. The second insulating layers 26 may each include an insulating material such as oxide or nitride.

The second insulating layers 26 may extend all the way around the supports 23. Around the supports 23, the gate structure GST may include the first insulating layers 22A and 22B and the second insulating layers 26 that are alternately stacked. As an example, the second insulating layers 26 may be located between the supports 23 and the conductive layers 21A and 21B, respectively.

According to the structure described above, the contact structure CT may be located between the supports 23 and the second portion CT_P2 may contact the supports 23. The first portion CT_P1 may be spaced apart from the supports 23, and the first insulating layers 22A and 22B and the second insulating layers 26 may be alternately stacked between the first portion CT_P1 and the supports 23. Accordingly, damage to peripheral layers due to sacrificial layers remaining between the contact structure CT and the supports 23 can be prevented or reduced. As an example, in the manufacturing process, sacrificial layers located between the first portion CT_P1 and the supports 23 are replaced with the second insulating layers 26 in advance, so that sacrificial remnants can be prevented or reduced. Similarly, remnants of a source gas used during manufacturing can be prevented or reduced.

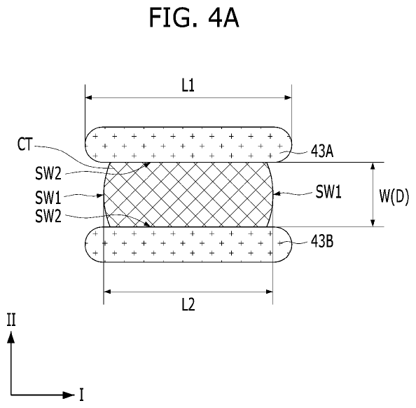

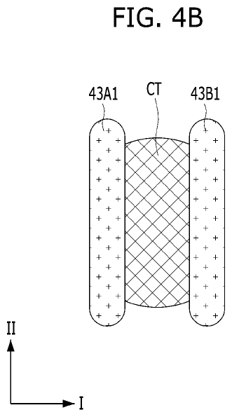

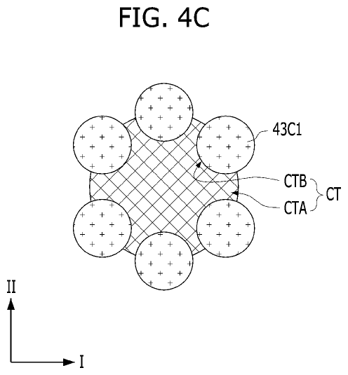

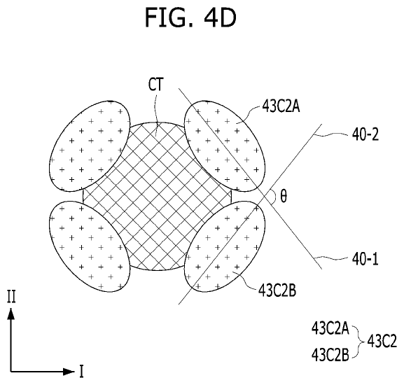

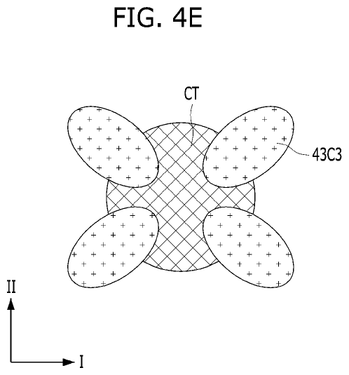

FIGS. 4A to 4E are horizontal cross-sectional diagrams illustrating the structure of a semiconductor device in accordance with an embodiment.

Referring to FIG. 4A, the semiconductor device may include a first support 43A, a second support 43B, and a contact structure CT. The first support 43A and the second support 43B may extend in the first direction I and may be separated from each other by a contact structure CT but nevertheless considered herein as being adjacent to each other in the second direction II. As shown in FIG. 4A, the supports 43A and 43B have horizontal cross section shapes, comprise two substantially parallel sides, the ends of which are “connected” to substantially semicircular ends. The horizontal cross-sectional shapes of the supports 43A and 43B are thus considered to be obround. The contact structure CT may be located between and abutting the first support 43A and the second support 43B. The contact structure CT may extend in the first direction I along substantially flat sidewalls of the first support 43A and the second support 43B. The contact structure CT may include two, slightly convex but substantially parallel first sidewalls SW1 separated from each other by a separation distance L2 but nevertheless considered herein as being adjacent to each other in the first direction I. The contact structure CT may also include two, substantially planar and substantially parallel second sidewalls SW2 separated from each other by the width W of the contact structure CT. The second side walls abut supports 43A and 43B and are considered herein as being adjacent to each other in the second direction II. The horizontal cross-sectional shape of the contact structure CT is thus considered to be substantially obround.

The contact structure CT may have a second length L2 in the first direction I and a width W in the second direction II. The second length L2 may be greater than the width W. The width W may be defined by a distance D between the first support 43A and the second support 43B. The distance D and the width W may be substantially the same. The first support 43A may have a first length L1, and the second length L2 may be smaller than the first length L1.

Referring to FIG. 4B, the semiconductor device may include a first support 43A1, a second support 43B1, and a contact structure CT. The first support 43A1 and the second support 43B1 may extend in the second direction II and may be adjacent to each other in the first direction I. The contact structure CT may be located between the first support 43A1 and the second support 43B1. The contact structure CT may extend in the second direction II along sidewalls of the first support 43A1 and the second support 43B1.

Referring to FIG. 4C, a plurality of supports 43C1, each having a round horizontal cross-sectional shape, may be located partially inside and evenly distributed “around” the 360-degree periphery of contact structure CT, horizontal cross-sectional shape of which is also round, corresponding to a contact structure, the shape of which may be a column or a truncated right circular cone. As an example, the supports 43C1 may be located along or “inside” the circumference of a columnar or cone-shaped contact structure CT. The “center” of each support 43C1 may also be located at a vertex of a polygon, having its own center at the “center” of the contact structure CT. The supports 43C1 may be arranged to surround the contact structure CT, and have circle-shaped segments of the supports 43C1 that may protrude into the contact structure CT. In a geometric plane defined by the first direction I and the second direction II and having a normal in the third direction III, the support 43C1 may have horizontal cross-sectional shapes that include but which are not limited toa circle, an ellipse, or a polygon. The supports 43C1 may thus have three-dimensional shapes that may include columnar, conical, catenoid or ellipsoid.

The contact structure CT may include protruding circular segment portions CTA and intruding concave portions CTB between each support 43C1. The protruding portions CTA and the intruding concave portions CTB may be alternately arranged along an edge of the contact structure CT. The protruding portions CTA may protrude between the supports 43C1. The intruding concave portions CTB may be located between the protruding portions CTA, and the supports 43C1 may be located in the concave portions CTB, respectively. The supports 43C1 thus have corresponding, “mirror-image” protruding and intruding portions.

Referring to FIGS. 4D and 4E, ellipsoid-shaped supports 43C2 and 43C3 may be located around the contact structure CT. In the plane defined by the first direction I and the second direction II, the supports 43C2 and 43C3 may each have an elliptically shaped horizontal cross section, having a long axis and a short axis. In FIG. 4D, the ellipsoid shaped supports 43C2 may be arranged so that the angle θ between external extensions 40-1 and 40-2 of the long axes of adjacent supports 43C2 is substantially equal to ninety (90) degrees. The angle θ may be greater or less than ninety (90) degrees. As shown in FIG. 4E, the ellipsoid-shaped supports 43C3 may be arranged so that the long and short axes of adjacent ellipsoid-shaped supports are rotated around an axis in the third direction, by about ninety degrees. The contact area between the supports 43C3 and the contact structure CT may vary based on the arrangement of the supports 43C3. Referring to FIGS. 4D and 4E, the contact area between the supports 43C3 and the contact structure CT may be substantially the same as or larger than the contact area between the supports 43C2 and the contact structure CT.

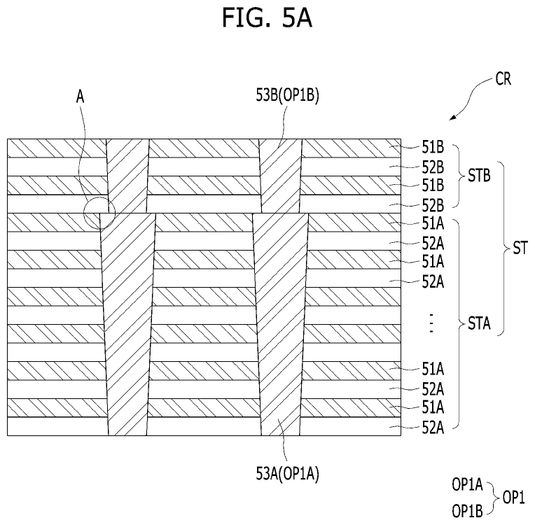

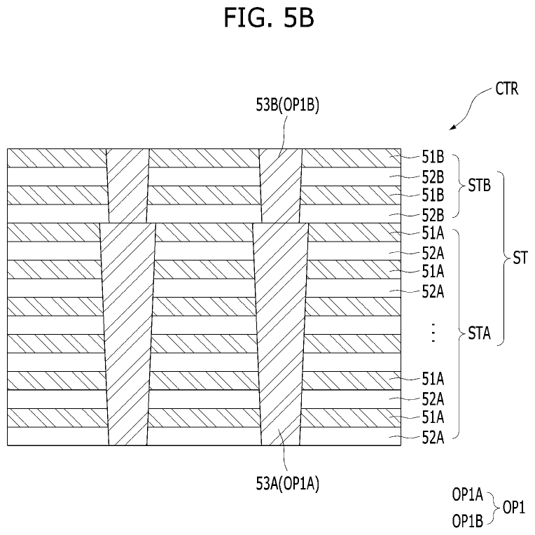

FIGS. 5A to 8A, FIGS. 5B to 8B, and FIGS. 9 to 13 depict steps of a manufacturing method of a semiconductor device in accordance with an embodiment. Hereinafter, the content overlapping with the previously described content will be omitted.

Referring to vertical cross sections shown in FIGS. 5A and 5B, a stack ST, which includes first material layers 51A and 51B and second material layers 52A and 52B that are alternately stacked, may be formed. As an example, a first substack STA, which includes the first material layers 51A and the second material layers 52A that are alternately stacked, may be formed. Subsequently, first openings OP1A may be formed in the first substack STA, and sacrificial layers 53A may be formed in the first openings OP1A. The first openings OP1A may have a uniform width or may have different widths according to levels. As an example, a lower portion of each of the first openings OP1A may have a smaller width than an upper portion thereof. Subsequently, a second substack STB including the first material layers 51B and the second material layers 52B that are alternately stacked may be formed on the first substack STA. Subsequently, first openings OP1B may be formed in the second substack STB, and a sacrificial layer 53B may be formed in the first openings OP1B. The first opening OP1 may be defined by the first opening OP1A and the first opening OP1B connected to each other. The first openings OP1B may have a uniform width or may have different widths according to levels. As an example, a lower portion of each of the first openings OP1B may have a smaller width than an upper portion thereof. At an interface between the first substack STA and the second substack STB, the first opening OP1A and the first opening OP1B may have different widths, and thus a step A may be caused on the sidewall of the first opening OP1.

The first material layers 51A and 51B may each include a material having a high etching selectivity with respect to the second material layers 52A and 52B. As an example, the first material layers 51A and 51B may each include a sacrificial material such as nitride, and the second material layers 52A and 52B may each include an insulating material such as oxide. The first material layers 51A and 51B may each include a conductive material such as polysilicon, tungsten, and molybdenum, and the second material layers 52A and 52B may each include an insulating material such as oxide. The sacrificial layer 53A may include a material having a high etching selectivity with respect to the first material layers 51A and 51B and the second material layers 52A and 52B. As an example, the sacrificial layer 53A may include tungsten. The stack ST may also include three or more substacks.

The stack ST, the first opening OP1, and the sacrificial layers 53A and 53B may be located in the cell region CR and the contact region CTR. The first opening OP1 located in the cell region CR may be used to form a channel structure. The first opening OP1 located in the contact region CTR may be used to form a support. The first openings OP1 of the cell region CR and the first openings OP1 of the contact region CTR may have substantially the same shape or different shapes. As an example, the first opening OP1 of the cell region CR and the first opening OP1 of the contact region CTR may each have a shape such as a circle, an ellipse, or a polygon. As an example, the first opening OP1 of the contact region CTR may have a longer length in the first direction I than the first opening OP1 of the cell region CR. The first opening OP1 of the cell region CR and the first opening OP1 of the contact region CTR may be formed simultaneously or formed in separate processes. The sacrificial layers 53A and 53B of the cell region CR and the sacrificial layers 53A and 53B of the contact region CTR may be formed simultaneously or formed in separate processes.

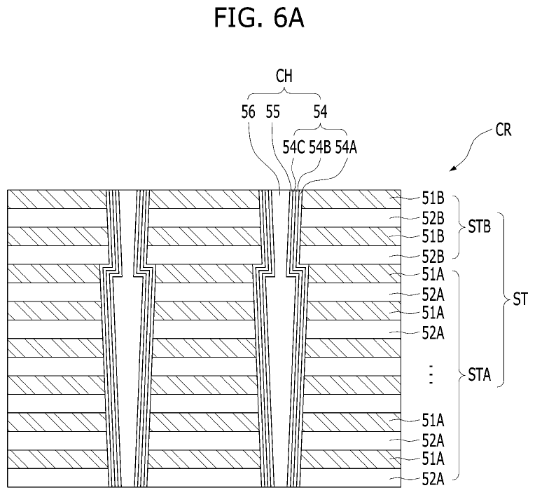

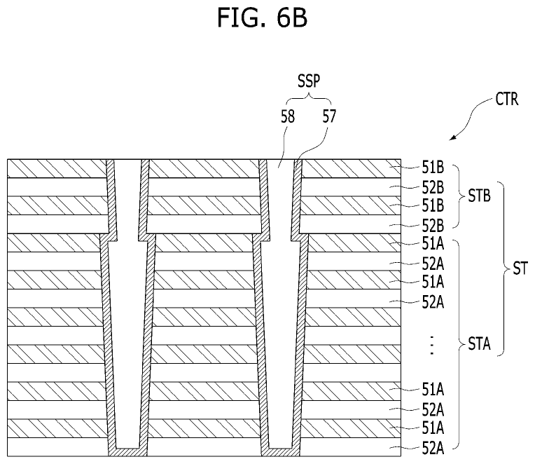

Referring to vertical cross sections shown in FIGS. 6A and 6B, the first opening OP1 may be reopened by removing the sacrificial layers 53A and 53B of the cell region CR. As an example, a mask pattern for opening the cell region CR may be formed, and the sacrificial layers 53A and 53B of the cell region CR may be selectively etched using a strip process. Subsequently, a channel structure CH may be formed in the first opening OP1. As an example, a memory layer 54 may be formed in the first opening OP1, a channel layer 55 may be formed in the memory layer 54, and an insulating core 56 may be formed in the channel layer 55. The memory layer 54 may include a blocking layer 54A, a data storage layer 54B, or a tunneling layer 54C, or a combination thereof. The data storage layer 54B may include a floating gate, polysilicon, a charge trap material, nitride, a variable resistance material, or the like. An electrode structure may also be formed instead of the channel structure CH. As an example, a variable resistance layer may be formed in the first opening OP1, an electrode layer may be formed in the variable resistance layer, and an insulating core may be formed in the electrode layer.

The first opening OP1 may be reopened by removing the sacrificial layers 53A and 53B of the contact region CTR. As an example, a mask pattern for opening the contact region CTR may be formed, and the sacrificial layers 53A and 53B of the contact region CTR may be selectively etched using a strip process. Subsequently, a sacrificial support SSP may be formed in the first opening OP1. The sacrificial support SSP may include an etch stop layer 57 or may include the etch stop layer 57 and a first sacrificial layer 58. As an example, the etch stop layer 57 may be formed in the first opening OP1, and the first sacrificial layer 58 may be formed in the etch stop layer 57. The etch stop layer 57 may include a material having a high etching selectivity with respect to the first material layers 51A and 51B and the second material layers 52A and 52B. The etch stop layer 57 may include aluminum oxide, titanium nitride, tungsten, or polysilicon, or a combination thereof.

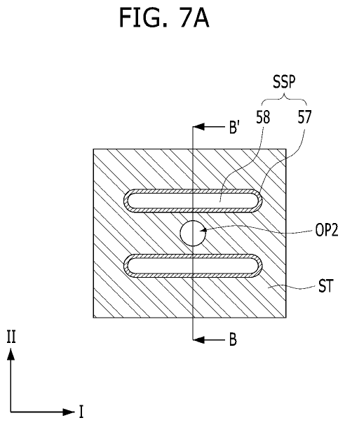

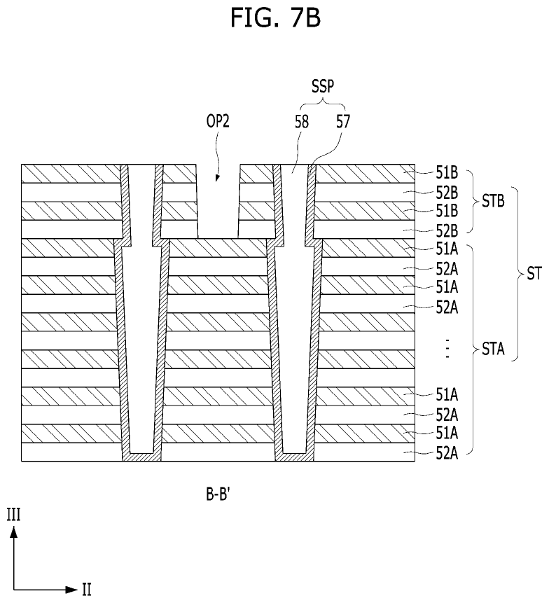

Referring to horizontal cross sections shown in FIGS. 7A and 7B, a second opening OP2 may be formed in the stack ST. The second opening OP2 may be located between the first openings OP1. As an example, the second opening OP2 may be located between the first openings OP1 adjacent to each other in the second direction II. The second opening OP2 may be spaced apart from the sacrificial supports SP and might not expose the sacrificial supports SP.

The second opening OP2 may have a shallower depth than the first opening OP1. The second opening OP2 may be used to form a contact plug. Considering a subsequent expansion process, the second opening OP2 may be formed to have a shallower depth than the depth of a contact plug to be formed.

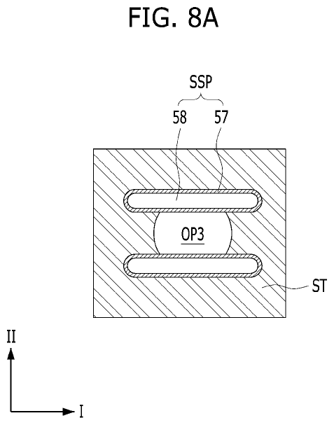

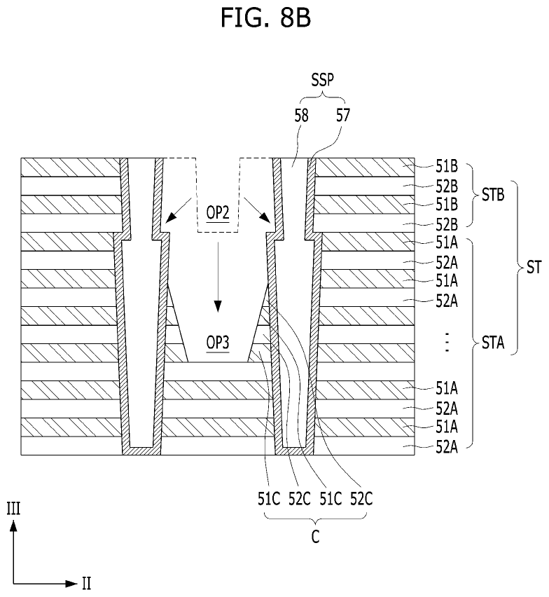

Referring to horizontal cross sections shown FIGS. 8A and 8B, a third opening OP3 may be formed in the stack ST. The first material layers 51A and 51B and the second material layers 52A and 52B may be etched through the second opening OP2, and the third opening OP3 may be formed by expanding the second opening OP2. When the first material layers 51A and 51B and the second material layers 52A and 52B are etched, the sacrificial supports SSP may be used as an etch stop layer. Accordingly, the size of the third opening OP3 may be controlled by the sacrificial supports SSP. The width of the third opening OP3 in the second direction II may be controlled by the sacrificial supports SSP.

The etch stop layer 57 may be exposed through the third opening OP3. The third opening OP3 may expose the etch stop layer 57 through the entire sidewall thereof or expose the etch stop layer 57 through some sidewalls thereof. As an example, an upper sidewall of the third opening OP3 may expose the etch stop layer 57, and a lower sidewall of the third opening OP3 may expose the first material layers 51A and 51B and the second material layers 52A and 52B.

In the process of expanding the second opening OP2 by etching the first material layers 51A and 51B and the second material layers 52A and 52B, a profile of the second opening OP2 may be transferred to the third opening OP3 as is, or may be partially changed. As an example, the lower sidewall of the third opening OP3 may have an inclined profile. Therefore, the lower sidewall of the third opening OP3 might not expose the etch stop layer 57, and the first material layers 51A and 51B and the second material layers 52A and 52B may remain between the third opening OP3 and the sacrificial supports SSP. Hereinafter, a region including the remaining first material layers 51C and the remaining second material layers 52C will be described as a remaining region C. The remaining region C may also exist around the step A.

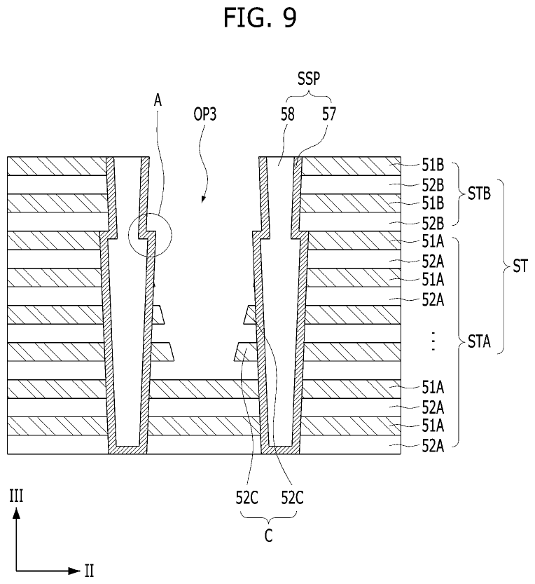

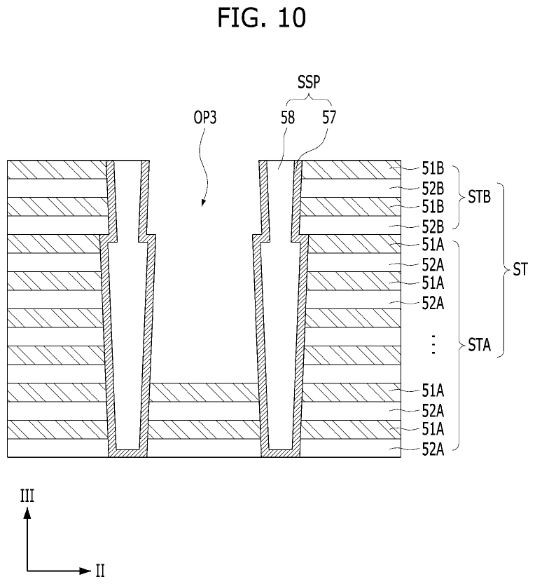

Referring to vertical cross sections shown in FIGS. 9 and 10, the remaining first material layers 51C and second material layers 52C may be removed through the third opening OP3. Through this, the width of a bottom surface of the third opening OP3 may be expanded. The etch stop layer 57 may be exposed through the remaining sidewalls of the third opening OP3, and generation of defects due to the remaining first material layers 51C and second material layers 52C in a subsequent process can be prevented or reduced.

First, referring to FIG. 9, the remaining first material layers 51C may be removed through the third opening OP3. The remaining first material layers 51C may be selectively etched with respect to the remaining second material layers 52C. Through this, the remaining second material layers 52C may protrude into the third opening OP3. The etch stop layers 57 may be exposed between the remaining second material layers 52C. As an example, in a case where the first material layers 51A and 51B are exposed through the bottom surface of the third opening OP3, when the remaining first material layers 51C are removed, the first material layers 51A and 51B on the bottom surface of the third opening OP3 may be removed together.

Subsequently, referring to FIG. 10, the remaining second material layers 52C may be removed through the third opening OP3. The remaining second material layers 52C may be selectively etched, and the etch stop layers 57 may be exposed. As an example, in a case where the second material layers 52A and 52B are exposed through the bottom surface of the third opening OP3, when the remaining second material layers 52C are removed, the second material layers 52A and 52B on the bottom surface of the third opening OP3 may be removed together.

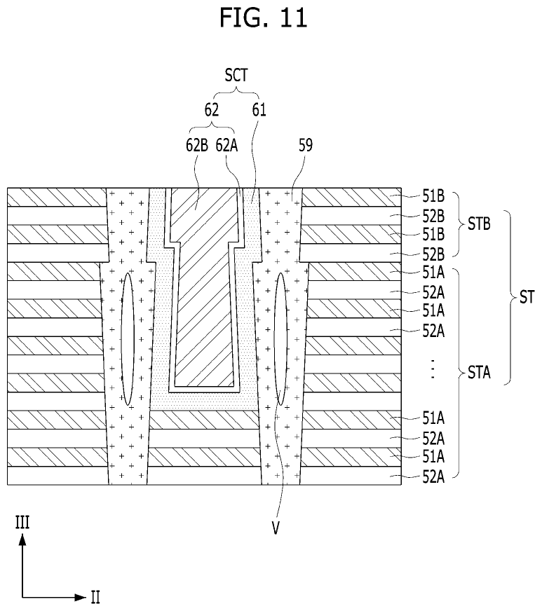

Referring to the vertical cross section shown in FIG. 11, a sacrificial contact structure SCT may be formed in the third opening OP3. As an example, an insulating layer 61 may be formed in the third opening OP3, and a second sacrificial layer 62 may be formed in the insulating layer 61. The second sacrificial layer 62 may include a material having a high etching selectivity with respect to the first material layers 51A and 51B and the second material layers 52A and 52B. The second sacrificial layer 62 may be a single layer or a multilayer. As an example, the second sacrificial layer 62 may include a barrier layer 62A and a metal layer 62B. The barrier layer 62A may include metal nitride such as titanium nitride, and the metal layer 62B may include a gap-fill metal material such as tungsten and molybdenum.

Subsequently, the sacrificial supports SSP may be replaced with supports 59. As an example, the first openings OP1 may be reopened by removing the sacrificial supports SSP. Subsequently, the supports 59 may be formed in the first openings OP1. The supports 59 may each include an insulating material such as oxide or nitride. The support 59 may include a void V therein. The void V may be an empty space caused in a deposition process.

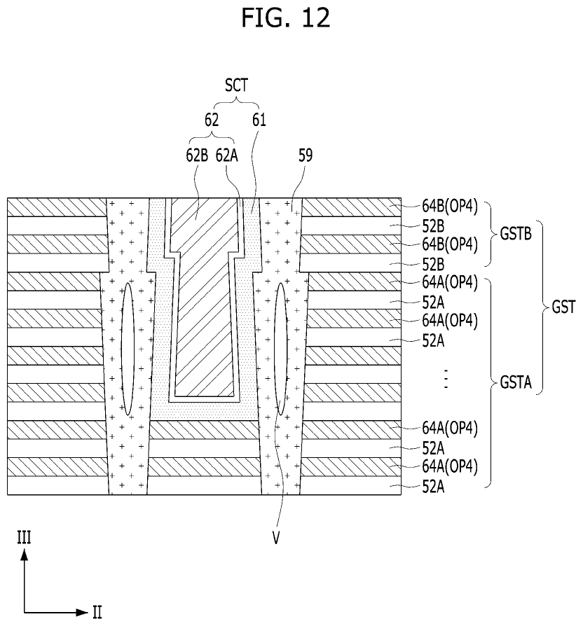

Referring to vertical cross section shown in FIG. 12, the first material layers 51A and 51B may be replaced with third material layers 64A and 64B. Through this, a gate structure GST may be formed. The gate structure GST may include a first substack GSTA and a second substack GSTB. The first substack GSTA may include the third material layers 64A and the second material layers 52A that are alternately stacked. The second substack GSTB may include the third material layers 64B and the second material layers 52B that are alternately stacked. When the first material layers 51A and 51B each include a conductive material, the replacement process may be omitted. Alternatively, a process such as silicidation for reducing the resistance of the first material layers 51A and 51B may also be performed.

As an example, after a slit passing through the stack ST is formed, the first material layers 51A and 51B may be selectively etched through the slit to form fourth openings OP4. Subsequently, the third material layers 64A and 64B may be formed in the fourth openings OP4, respectively. A metal layer may be deposited in the fourth openings OP4 by introducing a source gas into the fourth openings OP4 through the slit. The third material layers 64A and 64B may each include metal such as tungsten and molybdenum.

As described above, in the process of forming the third opening OP3 by expanding the second opening OP2, the remaining region C may be caused due to limitations of the etching process. When the remaining region C is not removed, the fourth opening OP4 may be formed in the remaining region C, and the third material layers 64A and 64B might not be sufficiently deposited in the fourth opening OP4. In such a case, a source gas may remain in the fourth opening OP4 and damage peripheral layers. Accordingly, by removing the remaining region C through an additional etching process, damage to the peripheral layers can be prevented or reduced.

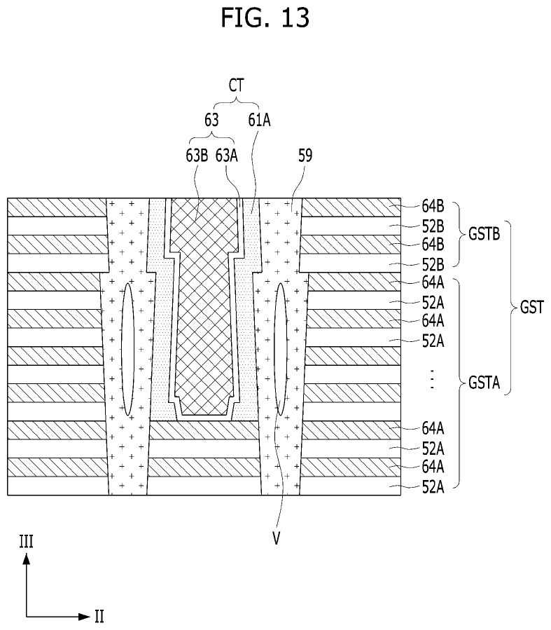

Referring to FIG. 13, the sacrificial contact structure SCT may be replaced with a contact structure CT. As an example, the second sacrificial layers 62 may be removed. Through this, the third opening OP3 may be partially opened. Subsequently, the insulating layer 61 may be etched to form an insulating spacer 61A. Through this, the third material layers 64A and 64B may be exposed through the bottom surface of the third opening OP3. Subsequently, a contact plug 63 may be formed in the third opening OP3. The contact plug 63 may include a single layer or a multilayer. The contact plug 63 may include a barrier layer 63A and a metal layer 63B in the barrier layer 63A. As an example, the barrier layer 63A may include metal nitride such as titanium nitride, and the metal layer 63B may include metal such as tungsten and molybdenum.

According to the manufacturing method described above, the contact structure CT located in the gate structure GST may be formed. The contact structure CT may extend through the gate structure GST and be electrically connected to at least one of the third material layers 64A and 64B. The semiconductor device may include a plurality of contact structures CT, and the contact structures CT having different depths may be connected to the third material layers 64A and 64B, respectively. Accordingly, the stack ST might not be patterned in a stepped shape.

The third opening OP3 may be formed by expanding the second opening OP2. Because the sacrificial supports SSP located around the second opening OP2 are used as etch stop layers, the size of the third opening OP3 may be controlled using the sacrificial supports SSP. The width of the third opening OP3 in the second direction II may be limited to a distance between the first openings OP1. Furthermore, as the remaining first material layers 51C are removed, damage to peripheral layers due to a remaining source gas can be prevented or reduced.

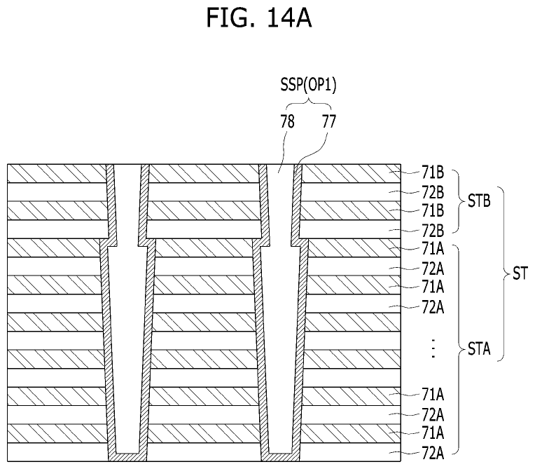

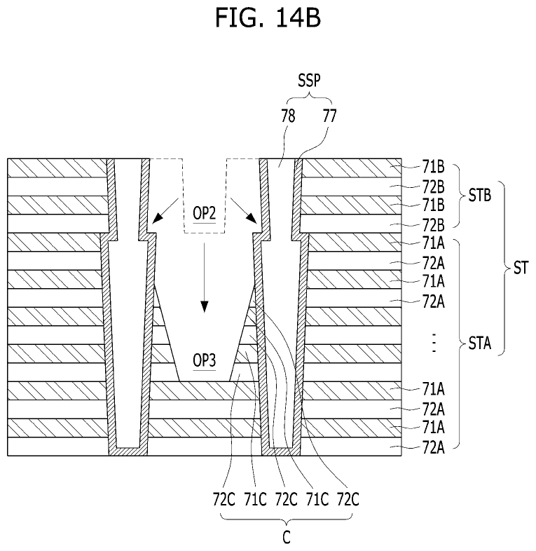

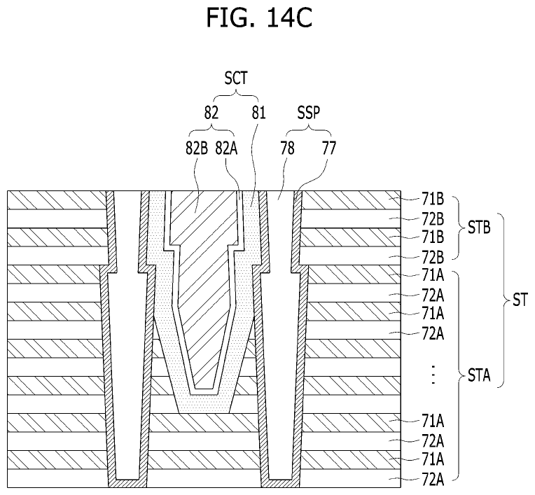

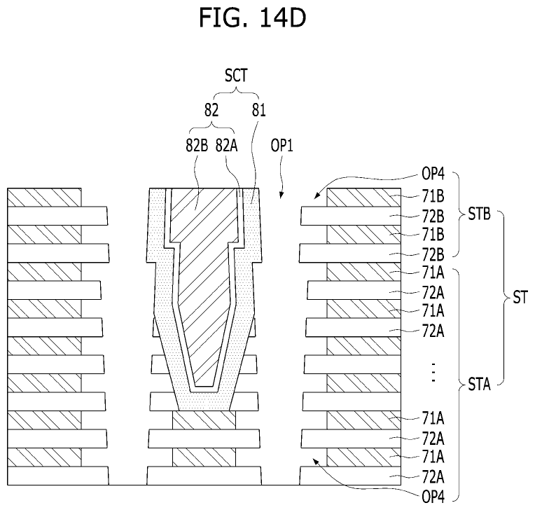

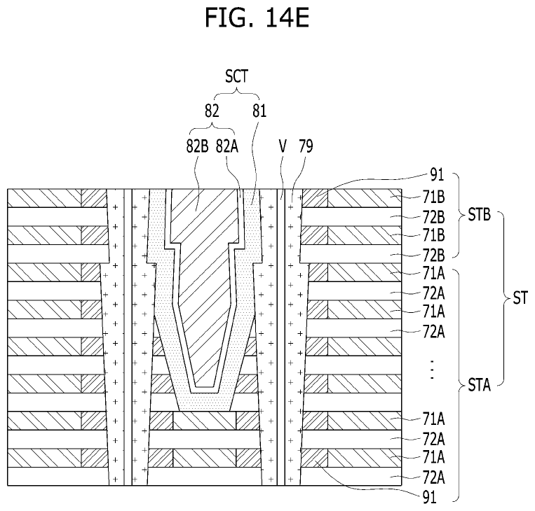

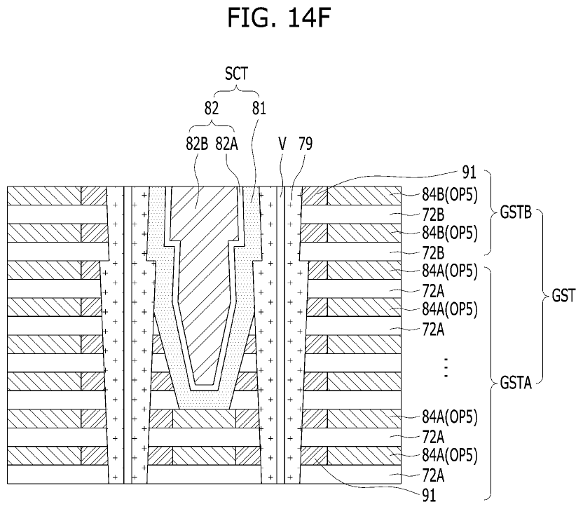

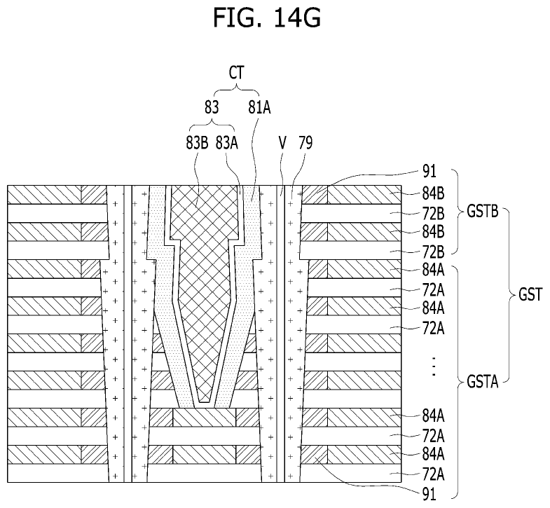

FIG. 14A to 14G are diagrams for describing a method of manufacturing a semiconductor device in accordance with an embodiment. Hereinafter, the description will be made by omitting the contents redundant with those described above.

Referring to FIG. 14A, a stack ST, which includes first material layers 71A and 71B and second material layers 72A and 72B that are alternately stacked, may be formed. As an example, a first substack STA may include the first material layers 71A and the second material layers 72A that are alternately stacked. A second substack STB may include the first material layers 71B and the second material layers 72B that are alternately stacked.

Subsequently, a first opening OP1 may be formed in the stack ST, and a sacrificial support SSP may be formed in the first opening OP1. As an example, an etch stop layer 77 may be formed in the first opening OP1, and a first sacrificial layer 78 may be formed in the etch stop layer 77. The etch stop layer 77 may include a material having a high etching selectivity with respect to the first material layers 71A and 71A and the second material layers 72A and 72B. The etch stop layer 77 may include aluminum oxide, titanium nitride, tungsten, or polysilicon, or a combination thereof.

Referring to FIGS. 14B and 14C, a sacrificial contact structure SCT may be formed in the stack ST. The sacrificial contact structure SCT may be located between the first openings OP1 and may contact the sacrificial supports SSP.

First, referring to FIG. 14B, a second opening OP2 may be formed in the stack ST. The second opening OP2 may be located between the sacrificial supports SSP. Subsequently, a third opening OP3 may be formed by expanding the second opening OP2. The third opening OP3 may be formed using the sacrificial supports SSP as etch stop layers. The sacrificial supports SSP may be exposed through some sidewalls of the third opening OP3. A lower sidewall of the third opening OP3 might not expose the sacrificial supports SSP. The first material layers 71A and 71B and the second material layers 72A and 72B may remain between the third opening OP3 and the sacrificial supports SSP. Hereinafter, a region including the remaining first material layers 71C and the remaining second material layers 72C will be described as a remaining region C.

Subsequently, referring to FIG. 14C, the sacrificial contact structure SCT may be formed in the third opening OP3. As an example, an insulating layer 81 may be formed in the third opening OP3, and a second sacrificial layer 82 may be formed in the insulating layer 81. The second sacrificial layer 82 may include a barrier layer 82A and a metal layer 82B.

Referring to FIG. 14D, the first openings OP1 may be opened by removing the sacrificial supports SSP. The sacrificial contact structure SCT, the first material layers 71A and 71B, and the second material layers 72A and 72B may be exposed through the first openings OP1.

Subsequently, the first material layers 71A and 71B may be selectively etched through the first openings OP1. Through this, the first material layers 71A and 71B around the first openings OP1 may be etched, and fourth openings OP4 connected to the first openings OP1 may be formed. The fourth openings OP4 may be located at substantially the same level as the first material layers 71A and 71B. As an example, the first material layers 71A and 71B around the sacrificial contact structure SCT may be etched. The fourth openings OP4 formed by etching the first material layers 71A and 71B in the remaining region CT may expose the sacrificial contact structure SCT.

Referring to FIG. 14E, insulating layers 91 may be formed in the fourth openings OP4. The insulating layers 91 may each include an insulating material such as oxide or nitride. Through this, the first material layers 71A and 71B around the first openings OP1 may be replaced with the insulating layers 91.

Subsequently, supports 79 may be formed in the first openings OP1. The supports 79 may each include an insulating material such as oxide or nitride. The support 79 may include a void V therein.

Referring to FIG. 14F, the first material layers 71A and 71B may be replaced with third material layers 84A and 84B. Through this, a gate structure GST may be formed. The gate structure GST may include a first substack GSTA and a second substack GSTB. The first substack GSTA may include the third material layers 84A and the second material layers 72A that are alternately stacked. The second substack GSTB may include the third material layers 84B and the second material layers 72B that are alternately stacked.

As an example, after a slit passing through the stack ST is formed, the first material layers 71A and 71B may be selectively etched through the slit to form fifth openings OP5. Subsequently, the third material layers 84A and 84B may be formed in the fifth openings OP5, respectively. As described above, even though the remaining region C is generated in the process of expanding the second opening OP2 to the third opening OP3, the remaining first material layers 71C may be replaced with the insulating layers 91 through the first openings OP1. Accordingly, the fifth openings OP5 might not be formed in the remaining region C, and damage to peripheral layers due to a remaining source gas in the remaining region C can be prevented or reduced.

Referring to FIG. 14G, the sacrificial contact structure SCT may be replaced with a contact structure CT. As an example, the second sacrificial layers 82 may be removed. Through this, the third opening OP3 may be partially opened. Subsequently, the insulating layer 81 may be etched to form an insulating spacer 81A. Through this, the third material layers 84A and 84B may be exposed through the bottom surface of the third opening OP3. Subsequently, a contact plug 83 may be formed in the third opening OP3. The contact plug 83 may include a single layer or a multilayer. The contact plug 83 may include a barrier layer 83A and a metal layer 83B in the barrier layer 83A. As an example, the barrier layer 83A may include metal nitride such as titanium nitride, and the metal layer 83B may include metal such as tungsten and molybdenum.

According to the manufacturing method described above, the remaining first material layers 71C may be replaced with insulating layers through the first opening OP1. Accordingly, in the process of replacing the first material layers 71A and 71B with the third material layers 84A and 84B, generation of a void in the remaining region C or damage to a peripheral layer due to a remaining source gas can be prevented or reduced.

Those of ordinary skill in the art should recognize that in various embodiments, the taper of a support and the taper of an associated contact structure are “mirror images” of each other. Which is to say that the tapers the supports and contact structures have similar shapes and similar sizes but the orientations of the tapers are reversed with reference to an intervening axis or plane between them. By way of example, the taper of a support that progressively narrows at lower levels of a gate structure may have an accompanying contact structure CT that progressively widens at the same lower levels.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, and changes for the embodiments may be made by those skilled in the art, to which the present disclosure pertains, without departing from the technical idea of the present disclosure defined in the following claims, and it should be construed that these substitutions, modifications, and changes belong to the scope of the present disclosure.

What is claimed is:

1. A semiconductor device comprising:
a gate structure including conductive layers and insulating layers that are alternately stacked;
tapered supports extending through the layers of the gate structure, each tapered support having a first width at a first level of the gate structure and a second width at a second level of the gate structure, the second width being smaller than the first width; and
a tapered contact structure located within the gate structure, between the tapered supports, the tapered contact structure having a third width at the first level of the gate structure and a fourth width at the second level of the gate structure, which is larger than the third width.

2. The semiconductor device of claim 1, wherein the tapered supports extend in a first direction and are separated from each other in a second direction, in a plane defined by the first direction and the second direction, the first and second directions being substantially orthogonal to each other.

3. The semiconductor device of claim 2, wherein a sidewall of the tapered contact structure extends in the first direction along and contacts sidewalls of the tapered supports.

4. The semiconductor device of claim 2, wherein the tapered contact structure comprises:
first sidewalls facing each other in the first direction; and
second sidewalls contacting the supports and facing each other in the second direction.

5. The semiconductor device of claim 2, wherein the tapered supports each have a first length in the first direction, and the tapered contact structure has a second length smaller than the first length in the first direction.

6. The semiconductor device of claim 1, wherein a portion of the tapered supports protrudes into the tapered contact structure.

7. The semiconductor device of claim 6, wherein the tapered contact structure comprises protruding portions located between the tapered supports and further comprises intruding concave portions between the protruding portions, wherein portions of the tapered supports are located in the intruding concave portions of the tapered contact structure.

8. The semiconductor device of claim 1, wherein the tapered contact structure contacts the tapered supports.

9. The semiconductor device of claim 1, wherein the tapered contact structure comprises:
a conductive contact plug electrically connected to at least one of the conductive layers; and
an insulating spacer surrounding a sidewall of the contact plug.

10. The semiconductor device of claim 1, wherein between the first level and the second level, an upper portion of each of the tapered supports has a larger width than a lower portion thereof, and a lower portion of the tapered contact structure has a larger width than an upper portion thereof.

11. A semiconductor device comprising:
a gate structure including conductive layers and first insulating layers that are alternately stacked;
supports extending through the layers of the gate structure; and
a contact structure located between the supports in the gate structure, and electrically connected to at least one of the conductive layers,
wherein the contact structure includes a first portion spaced apart from the supports and a second portion contacting the supports, and
the gate structure includes the first insulating layers and second insulating layers that are alternately stacked between the supports and the first portion.

12. The semiconductor device of claim 11, wherein the gate structure includes a first substack and a second substack, and
the first portion is located in the first substack and the second portion is located in the second substack.

13. The semiconductor device of claim 12, wherein in the second substack, the supports are tapered and wherein each tapered support has a first width at a first level of the gate structure and a second width smaller than the first width at a second level of the gate structure, and the second portion has a third width at the first level of the gate structure and a fourth width greater than the third width at the second level of the gate structure.

14. The semiconductor device of claim 12, wherein in the first substack, the supports are tapered and wherein each tapered support has a fifth width at a third level of the gate structure and a sixth width smaller than the fifth width at a fourth level of the gate structure, and the first portion has a seventh width at the third level of the gate structure and an eighth width smaller than the seventh width at the fourth level of the gate structure.
